(19) United States
(12) Patent Application Publication
(10) Pub. No.: US 2007/0190742 A1
(43) Pub. Date: Aug. 16, 2007

(54) Semiconductor device including shallow trench isolator and method of forming same

(75) Inventors: You-Hua Chou, Taipei City (TW); Hung Jui Chang, Changhua County (TW); Chin Kun Lan, Hsinchu City (TW); Yi-Ming Chen, Tainan City (TW)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Taiwan Semiconductor Manufacturing Company, Ltd.

(21) Appl. No.: 11/354,952

(22) Filed: Feb. 16, 2006

(51) Int. Cl. H01L 21/76

(52) U.S. Cl. 438/424

(57) ABSTRACT

A semiconductor device and method of manufacturing include an STI trench having a low-k dielectric material as a liner oxide layer and a bulk oxide trench fill layer.

### TECHNICAL FIELD

The present invention generally relates to a semiconductor device and a method of making a semiconductor device. More particularly, this invention relates to semiconductor devices including low dielectric constant materials in isolation trenches, and methods for manufacturing such devices.

### DESCRIPTION OF THE RELATED ART

In the semiconductor industry today, increasing numbers of ever-shrinking semiconductor devices are built on a single chip. Every device on the chip must be electrically isolated to ensure that it operates without interfering with another adjacent device. The art of isolating semiconductor devices and separating different functional regions on a chip has become an important aspect of modem metal-oxide-semiconductor (MOS) and bipolar integrated circuit (IC) technology. Improper electrical isolation among devices can cause current leakage or capacitive interference with the devices.

Shallow trench isolation (STI) is one preferred electrical isolation technique for ICs, and appears to have replaced the isolation technique of local oxidation of silicon (LOCOS). Conventional methods of producing a STI feature include: forming a hard mask over a targeted trench layer, patterning a soft mask over the hard mask, etching the hard mask through the soft mask to form a patterned hard mask, and using the patterned hard mask to etch the targeted trench layer to form trenches. Subsequently, the soft mask is removed (e.g., stripped) and each trench is filled with a dielectric material, typically having a dielectric constant of about 3.5, to complete formation of the STI feature.

As device dimensions continue to shrink, the size of STI regions between devices also shrinks. When the STI regions are reduced in size and IC performance is expected to improve, effects of scaled down device dimensions become more prominent. For example, STI trenches filled with material having a dielectric constant of 3.5 are no longer sufficient to isolate active device regions from each other, and the STI trenches may begin to act as small capacitors within the substrate. Thus, smaller, deeper (e.g., higher aspect ratio) STI trenches begin to exhibit an increased capacitive effect that can be detrimental to IC performance.

The present invention is directed to overcome one or more of the problems of the related art.

### SUMMARY OF THE INVENTION

In accordance with the purpose of the invention as embodied and broadly described, there is provided a method of manufacturing a semiconductor device, comprising: providing a substrate; forming an oxide layer over the substrate; forming a nitride layer over the pad oxide layer; forming an organic layer over the nitride layer; forming a photoresist layer over the organic layer; patterning the photoresist layer to form a photoresist mask including an opening for a trench to be formed in said substrate; etching the organic layer, the nitride layer, and the oxide layer through the opening in the photoresist mask to expose a portion of the substrate; etching the exposed portion of the substrate to form the trench in the substrate; removing the photoresist mask; forming a porous silicon oxide liner layer in the trench by PECVD; and filling the trench with an isolation oxide.

In accordance with the present invention, there is also provided a method of manufacturing a semiconductor device, comprising: providing a substrate; forming an oxide layer over the substrate; forming a nitride layer over the oxide layer; forming an organic layer over the nitride layer; forming a photoresist layer over the organic layer; patterning the photoresist layer to form a photoresist mask including an opening for a trench to be formed in said substrate; etching the organic layer, the nitride layer, and the oxide layer through the openings in the photoresist mask to expose a portion of the substrate; etching the exposed portion of the substrate to form the trench in the substrate; removing the photoresist mask; forming a first porous silicon oxide liner layer in the trench by PECVD; forming a second porous silicon oxide liner layer on the first liner layer by PECVD; and filling the trench with an isolation oxide.

In accordance with the present invention, there is also provided a method of manufacturing a semiconductor device, comprising: providing a substrate; forming an oxide layer over the substrate; forming a nitride layer over the pad oxide layer; forming an organic layer over the nitride layer; forming a photoresist layer over the organic layer; patterning the photoresist layer to form a photoresist mask including an opening for a trench to be formed in said substrate; etching the organic layer, the nitride layer, and the oxide layer through the opening in the photoresist mask to expose a portion of the substrate; etching the exposed portion of the substrate to form the trench in the substrate; removing the photoresist mask; forming a plurality of porous silicon oxide liner layers in the trench by PECVD; and filling the trench with an isolation oxide.

In accordance with the present invention, there is also provided a semiconductor device, comprising: a substrate; an oxide layer over the substrate; a nitride layer over the oxide layer; an organic layer over the nitride layer; a trench in the substrate; a porous PECVD silicon oxide liner layer in the trench; and an isolation oxide covering the liner layer.

In accordance with the present invention, there is also provided a semiconductor device, comprising: a substrate; an oxide layer over the substrate; a nitride layer over the oxide layer; an organic layer over the nitride layer; a trench in the substrate; a first porous PECVD silicon oxide liner layer in the trench; a second porous PECVD silicon oxide liner layer in the trench; and an isolation oxide covering the liner layer.

In accordance with the present invention, there is also provided a semiconductor device, comprising: a substrate; an oxide layer over the substrate; a nitride layer over the oxide layer; an organic layer over the nitride layer; a trench in the substrate; a plurality of porous PECVD silicon oxide liner layers in the trench; and an isolation oxide covering the plurality of liner layers.

Additional features and advantages of the invention will be set forth in the description that follows, being apparent from the description or learned by practice of the invention. The features and other advantages of the invention will be realized and attained by the semiconductor device structures and methods of manufacture particularly pointed out in the written description and claims, as well as the appended drawings.

It is to be understood that both the foregoing general description and the following detailed description are exemplary and explanatory, and are intended to provide further explanation of the invention as claimed.

### BRIEF DESCRIPTION OF THE DRAWINGS

The accompanying drawings, which are incorporated in and constitute a part of this specification, illustrate embodiments of the invention and, together with the description, serve to explain the features, advantages, and principles of the invention.

In the drawings:

FIGS. 1-5 illustrate formation of an STI trench according to an embodiment of the present invention; and

FIG. 6 illustrates formation of an STI trench according to another embodiment of the present invention.

### DESCRIPTION OF THE EMBODIMENTS

Reference will now be made in detail to embodiments of the present invention, examples of which are illustrated in the accompanying drawings. Wherever possible, the same or similar reference numbers will be used throughout the drawings to refer to the same or like parts.

Embodiments consistent with the present invention provide for a method of manufacturing a semiconductor device that reduces the capacitive effect of STI.

To overcome drawbacks associated with the approaches in the related art discussed above, and consistent with an aspect of the present invention, a semiconductor device and its method of manufacture will next be described.

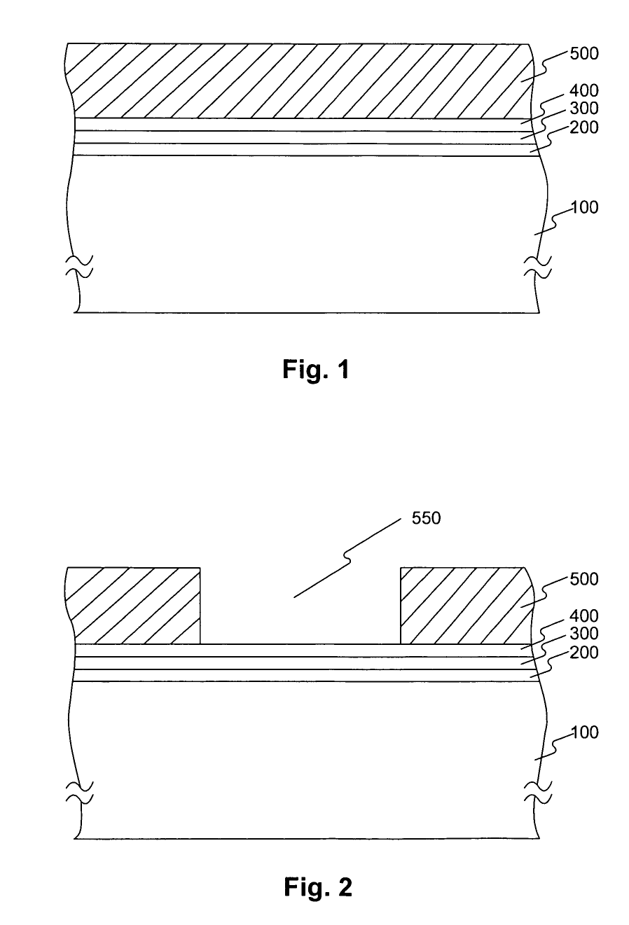

Embodiments consistent with the present invention include devices having STI and methods for forming the STI. FIGS. 1-5 illustrate a first embodiment for making such a device having a STI.

With reference to FIG. 1, a substrate 100, for example silicon, will undergo processing to form predetermined active regions and passive regions (not shown). Prior to forming trenches in the passive regions, a pad oxide layer 200 is thermally grown over the surface of the substrate, for example at a temperature in a range between about 850 to 950° C., to a thickness between about 190 to 210 Å. Alternatively, pad oxide layer 200 can be formed by an atmospheric or low pressure chemical vapor deposition (LPCVD) process. Other layers may also be used, consistent with the invention, depending on dimensions and aspect ratio of the to-be-formed trench.

Next, a nitride layer 300, for example SiN, is formed over the pad oxide layer, typically by reacting dichlorosilane (SiCl₂H₂) with ammonia (NH₃) in a LPCVD process at a temperature between about 750 to 800° C. The thickness of nitride layer 300 can be, for example, between about 1000 to 2000 Å. Formation of nitride layer 300 is followed by forming a bottom anti-reflective coating (BARC) layer 400 (e.g., an organic layer) over nitride layer 300. The thickness of BARC layer 400 is between about 200 to 500 Å. The BARC layer serves as an etch- or polish-stop for subsequent processing steps. Alternatively, silicon oxynitrides (SiOₓN_{y}) may be used in place of BARC layer 400. They are chemical vapor deposited (CVD) by reacting SiH₄ with N₂O and NH₃.

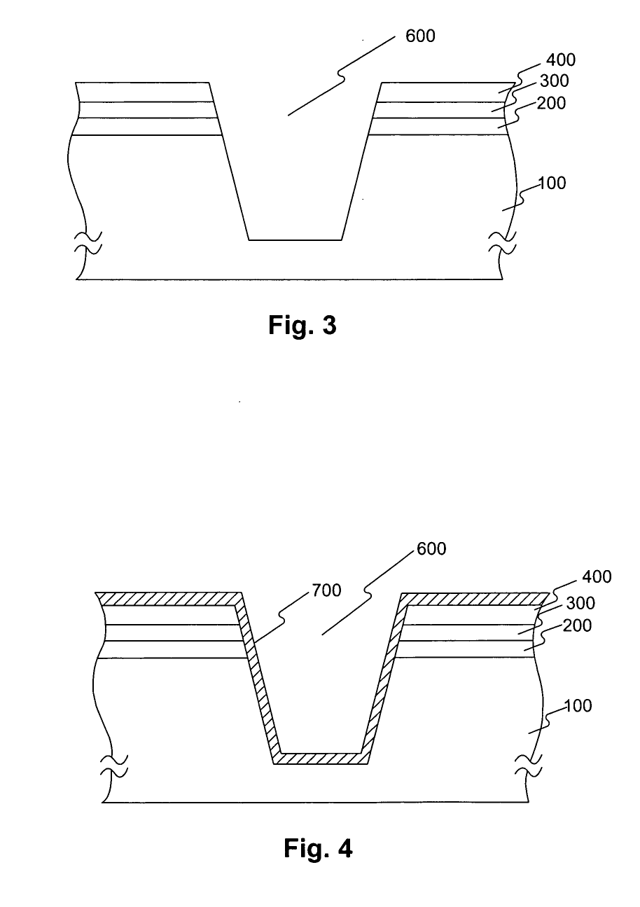

A photoresist layer 500 is next formed over BARC layer 400 and patterned to delineate the predetermined areas of passive regions where STI trenches will be formed. Then, as shown in FIG. 2, patterned openings 550 are formed in photoresist layer 500, and correspond to areas where trenches are to be formed. Areas that remain protected by photoresist layer 500 are areas where active regions will be formed. The thickness of photoresist layer 500 can be between about 0.4 to 0.6 μm. Using patterned photoresist layer 500 as a mask, BARC layer 400, nitride layer 300, and pad oxide layer 200 are then dry etched to expose portions of the underlying surface of substrate 100. This etching can be accomplished by using O₂/N₂ gases. Dry etching is followed by etching the substrate 100 to form a trench 600, as shown in FIG. 3. An exemplary depth of the trench is between about 3000 to 5000 Å, and can be formed by using an etch recipe comprising Cl₂ and HBr. Photoresist 500 is then removed using conventional stripping techniques (not shown).

Conventionally, STI trench formation would be completed by lining the inside walls of trench 600 with a thermal oxide (not shown) grown to a thickness between about 250 to 350 Å at a temperature between about 1000 to 1100° C. Further, conventionally, after the oxide lining layer is formed, another dielectric material, or isolation oxide (not shown), would be blanket deposited over the substrate, thus filling the trenches. Blanket dielectric layers may be formed from materials including silicon oxide materials, silicon nitride materials, and silicon oxynitride materials, by methods including CVD, plasma enhanced CVD (PECVD), and other physical vapor deposition (PVD) sputtering methods.

The isolation oxide may also be formed by a high-density plasma (HDP) CVD SiO₂ deposition. However, the dielectric material formed in this way typically has a dielectric constant of about 3.5, which may cause problems including an increased capacitive effect, as described above. HDP oxide deposition is known to fill the STI trenches better than PECVD methods. However, the HDP oxide deposition process requires application of a bias voltage to generate bombarding ions. These bombarding ions may damage the trench edge profile, such that the top corners of trench 600 may be rounded during the HDP process. Therefore, to protect the surface of trench 600, an oxide lining layer, which requires no voltage to form, is grown to protect the trench profile prior to the HDP process.

With reference to FIG. 4, and in accordance with an embodiment, instead of lining the inside walls of trench 600 with a 250 to 350 Å thermal oxide, as conventionally done, a low-k dielectric material is formed to line trench 600 by PECVD using SiH(CH₃)₃, i.e, trimethylsilane (TMS), which serves as a precursor to form a porous SiO₂ structure during the PECVD process. The source gas for the PECVD includes TMS and oxygen. The reaction of oxygen with TMS results in porous SiO₂ with organic branches (methyl group). Thus, a first porous SiO₂ low-k dielectric layer 700 is formed, as shown in FIG. 4. First porous SiO₂ low-k dielectric layer 700 may have a dielectric constant as low as about 2.5 to about 3.0 and a thickness from about 20 Å to about 100 Å.

TMS is sometimes used to form inter-metal level dielectrics in semiconductor devices (e.g., the insulating layers between successive metal layers above an active region of a semiconductor device), so that the process of forming the first porous SiO₂ low-k dielectric layer 700 is not more complex than other processes utilized in device fabrication. The methyl group of TMS can link, as a branch-like structure, with other TMS molecules to form a three dimensional structure. In addition, PECVD does not densify the deposited oxide of layer 700, in contrast to the densification and corresponding compressive stress that may occur during the ion bombardment in HDP.

According to embodiments consistent with the present invention, the low-k material used for first porous SiO₂ low-k dielectric layer 700 may replace all of the conventional oxide liner, part of the oxide liner, the trench fill material, or both the liner and the trench fill material.

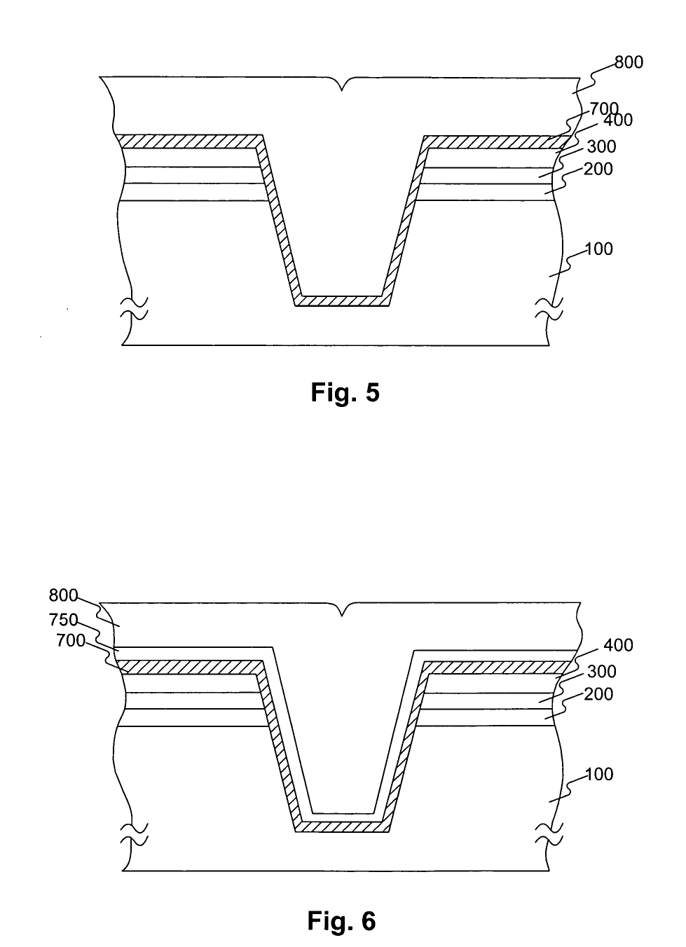

After formation of first porous SiO₂ low-k dielectric layer 700, trench 600 may be filled with an isolation oxide by blanket deposition of a silicon oxide 800, as shown in FIG. 5. Silicon oxide layer 800 may be blanket deposited by HDP as SiO₂, for example. Alternatively, silicon oxide layer 800 may also be deposited by forming a bulk SiO₂ layer by PECVD based on TMS.

The forming of the first porous SiO₂ low-k dielectric layer 700 by PECVD may also include using a silane precursor, while the forming of the isolation oxide, e.g. silicon oxide 800, is accomplished by PECVD using a TMS precursor. Alternatively, the forming of the first porous SiO₂ low-k dielectric layer 700 by PECVD may use a TMS precursor, while the forming of the isolation oxide is accomplished by HDP. Also consistent with the present invention, the forming of the isolation oxide, e.g., silicon oxide layer 800, may be accomplished by PECVD using a TMS precursor.

FIG. 6 illustrates another embodiment consistent with the present invention, in which a second porous SiO₂ low-k dielectric layer 750 may be formed over first porous SiO₂ low-k dielectric layer 700, prior to formation of silicon oxide layer 800. In this embodiment, layers 700 and 750 may serve as liner layers in trench 600. In general, liner layers are used to form protective and/or adhesion layers between substrate 100 and trench fill materials, discussed later. Additional liner layers may be present in trench 600 depending on the trench fill materials used and the dimensions of the trench. Such liners may have a total thickness from about 50 Å to about 300 Å. Each liner 700, 750, and any additional liner(s), may have a thickness from about 20 Å to 100 Å.

Either of first or second porous SiO₂ low-k dielectric layers 700/750 may be formed by PECVD based on silane, or by PECVD based on TMS, prior to formation of silicon oxide layer 800. Alternatively, first porous SiO₂ low-k dielectric layer 700, shown in FIG. 6, may be formed by PECVD utilizing a silane precursor, and second porous SiO₂ low-k dielectric layer 750 may be formed by PECVD utilizing a TMS precursor, prior to formation of silicon oxide layer 800. Consistent with this alternative, oxide layer 800 may also be formed by PECVD utilizing a TMS prescursor.

As another alternative process, first porous SiO₂ low-k dielectric layer 700 may be formed by PECVD including utilizing a silane precursor, and the second porous SiO₂ low-k dielectric layer 750 may be formed by PECVD including utilizing a TMS precursor. In this embodiment, oxide layer 800 may be formed by HDP or by PECVD utilizing a TMS precursor.

According to another embodiment consistent with the present invention, a plurality of porous SiO₂ low-k dielectric layers, like layers 700 and 750, may be formed by PECVD using at least one of a silane precursor and a TMS precursor. Consistent with this alternative, oxide layer 800 may be formed by HDP, or by PECVD using at least one of a silane precursor and a TMS precursor. Layers 700 and 750 are particularly beneficial when the device dimensions fall below 50 nm, where larger current may be required for device operation. When larger current is applied to the source and drain (not shown), low-k dielectric layers in isolation regions are increasingly important to prevent parasitic capacitive effects between adjacent isolated devices. Multiple layers, such as 700 and 750, improve device performance by reducing leakage current and increasing trench fill capability.

Thus, embodiments consistent with the present invention provide for a method of manufacturing a semiconductor device that reduces the capacitive effect of STI. Utilization of the low-k porous dielectric materials described herein will advantageously produce a STI with a reduced capacitive effect as device dimensions are shrunk. For example, in comparison with conventional SiO₂ and low-k porous dielectric material, the, low-k porous dielectric materials of the present invention realize a reduction in k value from about 3.4 to about 2.9. The same reduction is applicable to high aspect ratio STI trench profiles, where H₂ plasma may be used with TMS to deposit along the trench profile.

It will be apparent to those skilled in the art that various modifications and variations can be made in the disclosed structures and methods without departing from the scope or spirit of the invention. Other embodiments of the invention will be apparent to those skilled in the art from consideration of the specification and practice of the invention disclosed herein. It is intended that the specification and examples be considered exemplary only, with a true scope and spirit of the invention being indicated by the following claims.

1. A method of manufacturing a semiconductor device, comprising:
providing a substrate;
forming an oxide layer over the substrate;
forming a nitride layer over the oxide layer;
forming an organic layer over the nitride layer;
forming a photoresist layer over the organic layer;
patterning the photoresist layer to form a photoresist mask including an opening for a trench to be formed in said substrate;
etching the organic layer, the nitride layer, and the oxide layer through the opening in the photoresist mask to expose a portion of the substrate;
etching the exposed portion of the substrate to form the trench in the substrate;
removing the photoresist mask;
forming a porous silicon oxide liner layer in the trench by PECVD; and
filling the trench with an isolation oxide.

2. The method of manufacturing a semiconductor device according to claim 1, wherein the forming of the porous silicon oxide liner layer by PECVD includes using a silane precursor and the filling with the isolation oxide is accomplished by PECVD using a TMS precursor.

3. The method of manufacturing a semiconductor device according to claim 1, wherein the forming of the porous silicon oxide liner layer by PECVD includes using a TMS precursor and the filling with the isolation oxide is accomplished by HDP.

4. The method of manufacturing a semiconductor device according to claim 1, wherein the filling with the isolation oxide is accomplished by PECVD using a TMS precursor.

5. The method of manufacturing a semiconductor device according to claim 1, wherein the forming of the porous silicon oxide liner layer produces a layer with a dielectric constant of about 2.5 to about 3.0.

6. The method of manufacturing a semiconductor device according to claim 1, wherein the liner layer has a thickness from about 20 Å to about 100 Å.

7. A method of manufacturing a semiconductor device, comprising:
providing a substrate;
forming an oxide layer over the substrate;
forming a nitride layer over the oxide layer;
forming an organic layer over the nitride layer;
forming a photoresist layer over the organic layer;
patterning the photoresist layer to form a photoresist mask including an opening for a trench to be formed in said substrate;
etching the organic layer, the nitride layer, and the oxide layer through the openings in the photoresist mask to expose a portion of the substrate;
etching the exposed portion of the substrate to form the trench in the substrate;
removing the photoresist mask;
forming a first porous silicon oxide liner layer in the trench by PECVD;
forming a second porous silicon oxide liner layer on the first liner layer by PECVD; and
filling the trench with an isolation oxide.

8. The method of manufacturing a semiconductor device according to claim 7, wherein the forming of the first porous silicon oxide liner layer by PECVD includes using a silane precursor, and the forming of the second porous silicon oxide liner layer and the filling with the isolation oxide are both accomplished by PECVD using a TMS precursor.

9. The method of manufacturing a semiconductor device according to claim 7, wherein the forming of the first porous silicon oxide liner layer by PECVD includes using a silane precursor, the forming of the second porous silicon oxide liner layer by PECVD includes using a TMS precursor, and the filling with the isolation oxide is accomplished by HDP.

10. The method of manufacturing a semiconductor device according to claim 7, wherein the filling with the isolation oxide is accomplished by PECVD using a TMS precursor.

11. The method of manufacturing a semiconductor device according to claim 7, wherein the forming of the first porous silicon oxide liner layer produces a layer with a dielectric constant of about 2.5 to about 3.0.

12. The method of manufacturing a semiconductor device according to claim 7, wherein the forming of the second porous silicon oxide liner layer produces a layer with a dielectric constant of about 2.5 to about 3.0.

13. The method of manufacturing a semiconductor device according to claim 7, wherein the forming of the isolation oxide produces an oxide with a dielectric constant of about 2.5 to about 3.0.

14. The method of manufacturing a semiconductor device according to claim 7, wherein each of the first and second liner layers has a thickness from about 20 Å to about 100 Å.

15. A method of manufacturing a semiconductor device, comprising:
providing a substrate;
forming an oxide layer over the substrate;
forming a nitride layer over the pad oxide layer;
forming an organic layer over the nitride layer;
forming a photoresist layer over the organic layer;
patterning the photoresist layer to form a photoresist mask including an opening for a trench to be formed in said substrate;
etching the organic layer, the nitride layer, and the oxide layer through the opening in the photoresist mask to expose a portion of the substrate;
etching the exposed portion of the substrate to form the trench in the substrate;
removing the photoresist mask;
forming a plurality of porous silicon oxide liner layers in the trench by PECVD; and
filling the trench with an isolation oxide.

16. The method of manufacturing a semiconductor device according to claim 15, wherein the forming of the plurality of porous silicon oxide liner layers by PECVD includes using at least one of a silane precursor and a TMS precursor.

17. The method of manufacturing a semiconductor device according to claim 15, wherein the filling with the isolation oxide is accomplished by PECVD using one of a silane precursor and a TMS precursor.

18. The method of manufacturing a semiconductor device according to claim 15, wherein the forming of the plurality of porous silicon oxide liner layers by PECVD includes using at least one of a silane precursor and a TMS precursor, and the filling with the isolation oxide is accomplished by HDP.

19. The method of manufacturing a semiconductor device according to claim 15, wherein the filling with the isolation oxide is accomplished by PECVD using one of a silane precursor and a TMS precursor.

20. The method of manufacturing a semiconductor device according to claim 15, wherein the forming of the plurality of porous silicon oxide liner layers produces layers with a dielectric constant of about 2.5 to about 3.0.

21. The method of manufacturing a semiconductor device according to claim 15, wherein the forming of the isolation oxide produces an oxide with a dielectric constant of about 2.5 to about 3.0.

22. The method of manufacturing a semiconductor device according to claim 15, wherein each of the plurality of liner layers has a thickness from about 20 Å to about 100 Å.

23. A semiconductor device, comprising:
a substrate;
an oxide layer over the substrate;
a nitride layer over the oxide layer;
an organic layer over the nitride layer;
a trench in the substrate;
a porous PECVD silicon oxide liner layer in the trench; and
an isolation oxide covering the liner layer.

24. The semiconductor device according to claim 23, wherein the porous PECVD silicon oxide liner layer is formed using a silane precursor.

25. The semiconductor device according to claim 23, wherein the isolation oxide is formed by PECVD using a TMS precursor.

26. The semiconductor device according to claim 23, wherein the porous PECVD silicon oxide liner layer is formed using a TMS precursor and the isolation oxide is formed by HDP.

27. The semiconductor device according to claim 23, wherein the isolation oxide is formed by PECVD using a TMS precursor.

28. The semiconductor device according to claim 23, wherein the porous PECVD silicon oxide liner layer has a dielectric constant of about 2.5 to about 3.0.

29. The semiconductor device according to claim 23, wherein the isolation oxide has a dielectric constant of about 2.5 to about 3.0.

30. The semiconductor device according to claim 23, wherein the liner layer has a thickness from about 20 Å to about 100 Å.

31. A semiconductor device, comprising:
a substrate;
an oxide layer over the substrate;
a nitride layer over the oxide layer;
an organic layer over the nitride layer;
a trench in the substrate;
a first porous PECVD silicon oxide liner layer in the trench;
a second porous PECVD silicon oxide liner layer in the trench; and
an isolation oxide covering the liner layer.

32. The semiconductor device according to claim 31, wherein the first porous PECVD silicon oxide liner layer is formed using a silane precursor, and the second porous PECVD silicon oxide liner layer and the isolation oxide are formed using a TMS precursor.

33. The semiconductor device according to claim 31, wherein the first porous PECVD silicon oxide liner layer is formed using a silane precursor, the second porous PECVD silicon oxide liner layer is formed using a TMS precursor, and the isolation oxide is formed by HDP.

34. The semiconductor device according to claim 31, wherein the isolation oxide is formed by PECVD using a TMS precursor.

35. The semiconductor device according to claim 31, wherein the first porous PECVD silicon oxide liner layer has a dielectric constant of about 2.5 to about 3.0.

36. The semiconductor device according to claim 31, wherein the second porous PECVD silicon oxide liner layer has a dielectric constant of about 2.5 to about 3.0.

37. The semiconductor device according to claim 31, wherein the isolation oxide has a dielectric constant of about 2.5 to about 3.0.

38. The semiconductor device according to claim 31, wherein each of the first and second liner layers has a thickness of about 20 Å to about 100 Å.

39. A semiconductor device, comprising:
a substrate;
an oxide layer over the substrate;
a nitride layer over the oxide layer;
an organic layer over the nitride layer;
a trench in the substrate;
a plurality of porous PECVD silicon oxide liner layers in the trench; and
an isolation oxide covering the plurality of liner layers.

40. The semiconductor device according to claim 39, wherein the plurality of PECVD porous silicon oxide liner layers are formed using at least one of a silane precursor and a TMS precursor.

41. The semiconductor device according to claim 39, wherein the isolation oxide is formed by PECVD using one of a silane precursor and a TMS precursor.

42. The semiconductor device according to claim 39, wherein the plurality of PECVD porous silicon oxide liner layers are formed by using at least one of a silane precursor and a TMS precursor, and the isolation oxide is formed by HDP.

43. The semiconductor device according to claim 39, wherein the isolation oxide is formed by PECVD using one of a silane precursor and a TMS precursor.

44. The semiconductor device according to claim 39, wherein the plurality of porous PECVD silicon oxide liner layers has a dielectric constant of about 2.5 to about 3.0.

45. The semiconductor device according to claim 39, wherein the isolation oxide has a dielectric constant of about 2.5 to about 3.0.

46. The semiconductor device according to claim 39, wherein each of the plurality of liner layers has a thickness from about 20 Å to about 100 Å.
